(19) United States
(12) Patent Application Publication
(10) Pub. No.: US 2013/0256868 A1
(43) Pub. Date: Oct. 3, 2013

(54) THERMAL INTERFACE MATERIAL FOR SEMICONDUCTOR CHIP AND METHOD FOR FORMING THE SAME

(71) Applicant: Yevgeni ALIYEV, Ansan-si (KR)

(72) Inventor: Yevgeni ALIYEV, Ansan-si (KR)

(73) Assignee: SEOUL SEMICONDUCTOR CO., LTD., Seoul (KR)

(21) Appl. No.: 12/488,791

(22) Filed: Jun. 22, 2009

(30) Foreign Application Priority Data
Jun. 23, 2008 (KR) 10-2008-0058919

(51) Int. Cl. H01L 21/50; H01L 23/34

(52) U.S. Cl. CPC H01L 21/50; H01L 23/34
USPC 257/713; 438/122

(57) ABSTRACT

Disclosed is a method for forming a thermal interface material for a semiconductor chip, comprising the steps of forming an initial layer on a substrate, the initial layer including carbon nanotubes and nano metal powder; arranging a semiconductor chip on the initial layer; and heat-treating the initial layer with a sintering temperature of the nano metal powder to obtain a thermal interface material of the carbon nanotubes and the nano metal powder.

### CROSS-REFERENCE TO RELATED APPLICATION

This application claims priority from and the benefit of Korean Patent Application No. 10-2008-0058919, filed on Jun. 23, 2008, which is hereby incorporated by reference for all purposes as if fully set forth herein.

### BACKGROUND OF THE INVENTION

1. Field of the Invention

Exemplary embodiments of the present invention relate to a thermal interface material (TIM) for a semiconductor chip and a method for forming a thermal interface material is between a substrate and a semiconductor chip or die.

2. Discussion of the Background

It is critical how to perform thermal management for semiconductor chips in all electronic appliances. Conventionally, a thermally conductive adhesive, including an epoxy and the like, or an unleaded or leaded solder alloy may be used as a thermal interface material for electrically and/or thermally connecting a semiconductor chip with a substrate.

However, the conventional thermal interface material exhibits inferior thermal and electrical properties. The resistance of a thermal interface material may be expressed as Equation 1:

$$R = ρ \frac{H}{S}$$

where ρ the is thermal resistivity of the thermal interface material, H is the thickness of a thermal interface material, and S is the cross-sectional area of the thermal interface material.

Research for reducing thermal resistance of a thermal interface material has been performed. Some of this research focused on reducing thermal resistivity of a thermal interface material in order to increase thermal conductivity. Other research has focused on how to reduce the thickness H of a thermal interface material. Additional research has studied how to reduce the contact area S of a thermal interface material. However, many limitations still remain even though various studies and experiments as described above have been performed.

Typically, the thermal interface material includes a thermally conductive (or electrically conductive) filler and a matrix material. The filler may cause thermal transfer characteristics to be realized while the matrix material may cause the thermal interface material to be installed between a semiconductor chip and a substrate, particularly a heat sink.

As one of some new thermal interface materials, a thermal interface material in which carbon nanotubes (CNTs) are used as a base is known. It is well known that carbon nanotubes have a large thermal conductivity of about 3000 W/mK with respect to heat flowing along axial directions of the carbon nanotubes themselves [Dresselhaus et al., Phil. Trans. R. Soc. Lond. A 362, 2065 (2002)]. In comparison, the thermal conductivity of diamond ranges from about 900 W/mK to about 2300 W/mK, while the thermal conductivity of copper is about 400 W/mK. The thermal conductivity of carbon nanotubes is large in their inherent axial direction since vibrations of carbon atoms may be easily transmitted from the carbon nanotubes downwards. However, there is a problem in that the strength of the carbon nanotubes in the transversal direction which is vertical to their axial direction is considerably small and the transverse thermal conductivity of the carbon nanotubes along the transverse direction thereof is so remarkably small that it may be no more than about 1/100 of the axial thermal conductivity of the carbon nanotubes.

The carbon nanotubes are well mixed with plastics (polymer materials) to provide the appropriate conductivity under appropriate load conditions. In order to realize the thermal conductivity with a predetermined level, it is necessary that the aspect ratio of the filler is larger, while the load is smaller. Considering the above description, carbon nanotubes are ideal in that among carbon fibers, they have a largest aspect ratio. Further, the natural tendency of carbon nanotubes to form ropes may cause a very long thermal conductive path to be essentially realized even under a relatively small load condition.

FIG. 1A is a photographic view showing carbon nanotubes from Carbon Nanotechnologies Inc. (Houston, Tex.), which are well dispersed in polycarbonate, while FIG. 1B is a photographic view showing carbon nanotubes (Matthew M. F. Yuen and others, “CNT based is thermal interface material”, International Seminar on LEDs, Display and Lighting 2007, p. 7), which have been grown onto a substrate.

Carbon nanotubes may have the length controllable within a range of 100 nm to 100 μm and the diameter diversified in a range of tens to hundreds of nanometers. There are many patents relating to a thermal interface material in which carbon nanotubes are used as a base, the examples of which include U.S. Patent Application Publication No. 2007/0161729 A1; Chinese Patent No. 1990816; U.S. Pat. Nos. 6,965,513 B2 and 7,186,020 B2; U.S. Patent Application Publication No. 2007/0155136 A1, and the like.

A CNT TIM (carbon nanotube thermal interface material), i.e., a thermal interface material in which carbon nanotubes are used as a base, has a problem principally originating from base materials (for example, various polymer materials). Generally, the base materials cause thermal transfer time and temperature of the thermal interface material to be decreased. The thermal conductivity of the base material is so low, causing the thermal conductivity of the total thermal interface material system to be decreased. In case of some base materials, the mechanical strength and the reliability may also be typically decreased.

### SUMMARY OF THE INVENTION

Exemplary embodiments of the present invention provide a thermal interface material for a semiconductor chip, wherein the thermal conductivity of the thermal interface material is very large while the mechanical strength, reliability and durability of the thermal interface material is excellent.

Exemplary embodiments of present invention also provide a method for forming a is thermal interface material between a semiconductor chip and a substrate such as a heat sink, wherein the thermal conductivity of the thermal interface material is very large while the mechanical strength, reliability and durability of the thermal interface material is excellent.

Additional features of the invention will be set forth in the description which follows, and in part will be apparent from the description, or may be learned by practice of the invention.

An exemplary embodiment of the present invention discloses a method for forming a thermal interface material for a semiconductor chip, comprising of forming an initial layer comprising carbon nanotubes and nano metal powder on a substrate; disposing a semiconductor chip on the initial layer; and heat-treating the initial layer at a sintering temperature of the nano metal powder.

An exemplary embodiment of the present invention also discloses a thermal interface material, comprising a sintered product made of sintered nano metal powder and carbon nanotubes, wherein the sintered product is disposed between a substrate and a semiconductor chip.

An exemplary embodiment of the present invention also discloses an electronic device, comprising: a substrate; a semiconductor chip; and a sintered thermal interface material disposed between the substrate and the semiconductor chip, wherein the sintered thermal interface material comprises a vertical array of carbon nanotubes spaced apart from each other on the substrate and a nano metal powder infiltrated into the vertical array of carbon nanotubes.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1A is a photographic view showing conventional carbon nanotubes, which are dispersed in polycarbonate.

FIG. 1B is a photographic view showing carbon nanotubes which have been grown onto a substrate.

FIG. 2 is a sectional view illustrating a thermal interface material for a semiconductor chip according to an exemplary embodiment of the present invention.

FIG. 3 is a flow chart illustrating a method for forming a thermal interface material shown according to an exemplary embodiment of the present invention of FIG. 2.

FIG. 4 is a view illustrating a method for forming a thermal interface material according a first exemplary embodiment of the present invention.

FIG. 5 is a view illustrating a method for forming a thermal interface material according to a second exemplary embodiment of the present invention.

FIG. 6 is a view illustrating a method for forming a thermal interface material according to a third exemplary embodiment of the present invention.

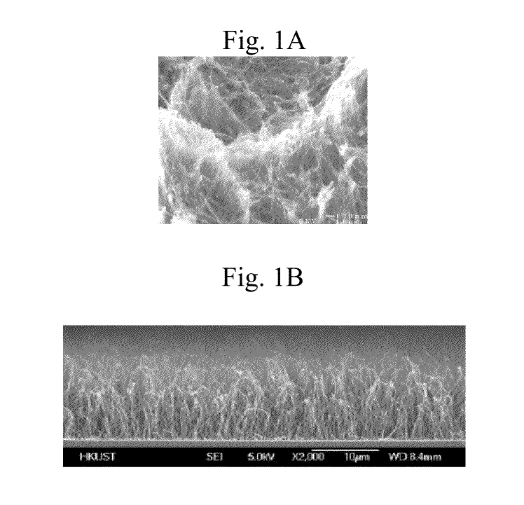

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

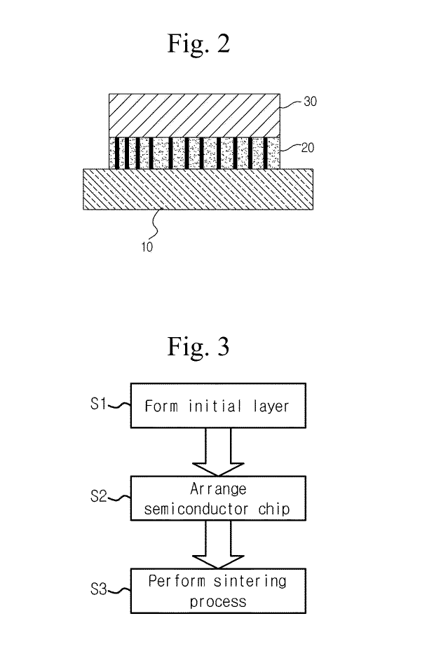

FIG. 2 is a sectional view illustrating a thermal interface material for a semiconductor chip according to an exemplary embodiment of the present invention, and FIG. 3 is a flow chart illustrating a method for forming the thermal interface material shown in FIG. 2.

Referring to FIG. 2, a thermal interface material 20 according to the present invention is interposed between a substrate 10 and a semiconductor chip 30. For example, the substrate 10 may be a heat sink which is appropriate for the heat radiation from the semiconductor chip 30 outwards. Further, the substrate 10 may be a conductive metal, which may be in electrical communication with the semiconductor chip 30. It is preferable that the semiconductor chip 30 be an optical semiconductor chip, such as a light emitting diode chip, which may emit light from a p-n semiconductor junction when electrical power is applied. The is thermal interface material 20 comprises a sintered material. The sintered material is formed by sintering nano metal powder of nano-sized metal particles. The sintered material includes carbon nanotubes (CNT). It is preferable that the metal from the nano metal powder and the carbon nanotubes be in contact with each other in the thermal interface material 20.

Referring to FIG. 3, a method for forming the thermal interface material 20 between the substrate 10 and the semiconductor chip 30 includes an initial layer (prior to sintering) forming step S1, a semiconductor chip arranging step S2, and a sintering step S3.

In the initial layer forming step S1, an initial layer which includes carbon nanotubes and nano metal powder is formed in a paste state. As respectively illustrated in other embodiments, as described below, the initial layer may be formed either by growing carbon nanotubes on a substrate and then applying a nano-sized metal paste including nano metal powder thereto or by applying to the substrate a CNT/nano-sized metal paste including carbon nanotubes and nano metal powder as the main components. At this time, additives, such as a binder, a dispersing agent, and a solvent, are added to the initial layer.

In the semiconductor chip arranging step S2, a semiconductor chip, preferably a light emitting diode chip, is arranged on the initial layer which exists in a paste state by being pressed with a predetermined pressure. In the subsequent sintering step S3, a structure, in which the substrate, the initial layer, and the semiconductor chip is laminated, is heat-treated at a sintering temperature for the nano metal powder so that the initial layer may be sintered to form an interconnection layer or a sintered layer, which serves as a thermal interface material. When the temperature is lowered below the sintering temperature, the additives are removed through evaporation, volatilization, decomposition, and the like.

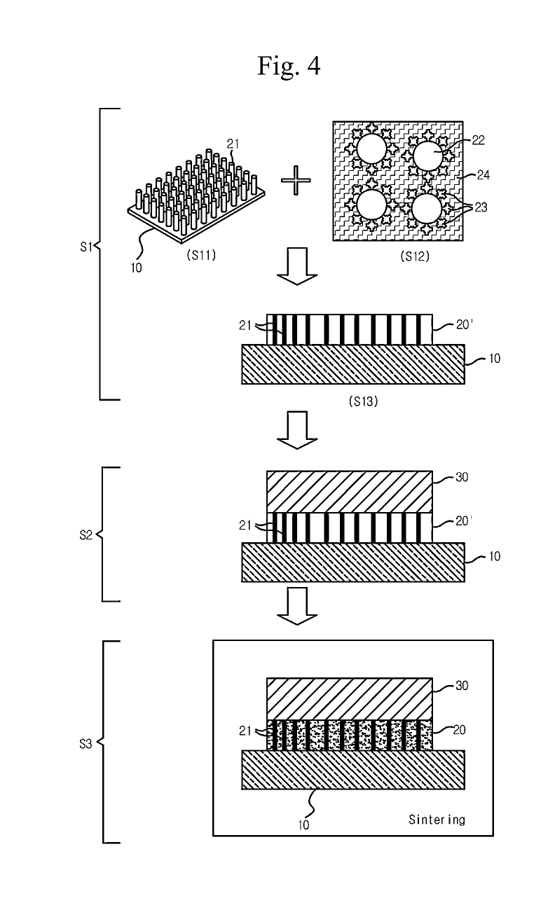

FIG. 4 is a view illustrating a method for forming or providing a thermal interface is material as a sintered layer between the substrate and the semiconductor chip according to a first exemplary embodiment of the present invention. FIG. 4 shows a specific example of the initial layer forming step S1, the semiconductor chip arranging step S2, and the sintering step S3 as described above, and the various steps shown in FIG. 4 contribute to forming a thermal transmission structure of superior quality.

First, in a first substep S11 of the initial layer forming step S1, an array of carbon nanotubes 21 spaced apart from each other are grown on the substrate 10 in a vertical direction. The array of carbon nanotubes is available from “Nano-Lab, Inc.”

In a second substep S12 of the initial layer forming step S1, a paste including nano metal powder, i.e., nano-sized metal powder, is provided. Any metal such as Ag, Cu, etc. or various metal mixtures may be used as the nano metal powder. The particle size of the nano metal powder ranges from 100 nm to 500 nm.

As commercial providers for the nano metal powder, there may be included “Nanostructured & Amorphous Materials, Inc.,” “Inframat Advanced Materials, Inc.,” “Sumitomo electric U.S.A, Inc.” and “Kemco International Associates.”

An appropriate amount of the nano metal powder is mixed with a dispensing agent 23 for dispersing nano metallic particles 22 and preventing them from cohering and a binder capable of preventing paste from degenerating during treatment and drying processes of the paste. In some cases, the nano metal powder may be mixed with a solvent for controlling the viscosity of the paste. In FIG. 4, the solvent and the binder is designated by reference numeral 24.

Various kinds of dispensing agents may be used in this embodiment, including fatty acid, fish oil, polydiallyldimethylammonium chloride (PDDA), polyacryl acid (PAA), is polystyrene sulfonate (PSS), and the like may be used as the dispensing agent 23. For example, polyvinyl alcohol (PVA), polyvinyl butyral (PVB), wax, and the like may used as the binder. Since the binder should be boiled, evaporated, or decomposed below the sintering temperature, the properties (for example, volatile temperature) of the binder need to be matched with the sintering temperature for the respective nano metal powder. The solvent for reducing the viscosity of the paste may be variously selected depending on the specific binder being used, wherein “Haraeus HVS 100,” “Texanol,” “Terpineol,” “Haraeus RV-372,” “Haraeus RV-507,” and the like may be used as the solvent. In substep S12, placing the nano metal particles into an ultrasonic bath operating at room temperature or a cold water bath assists in dispersing the nano metal particles in order to prevent the nano metal powder from being heated and, accordingly, sintered. In addition, stirring and/or vibrating may also help disperse the nano metal particles in the binder.

In the third substep S13 of the initial layer forming substep S1, the nano metal paste is applied to the substrate 10 on which the array of carbon nanotubes 21 spaced apart from each other has been previously grown, so that the nano metal paste may be uniformly infiltrated into the structure of the array of carbon nanotubes, i.e., between the array of carbon nanotubes 21. In order to improve the infiltration and the uniformity of the nano metal paste, an ultrasonic bath or some vibration mechanisms may be used.

In this exemplary embodiment, after the first substep S11, the second substep S12, and the third substep S13 are performed, an initial layer 20′, which is composed of the array of carbon nanotubes 21 and the nano metal paste in a paste state that includes nano metal powder as the main component, is formed on the substrate 10. At this time, the sequence of the first substep S11 and the second substep S12 may be interchanged.

Then, the semiconductor chip arranging step S2 is performed so that the semiconductor chip 30 is arranged on the initial layer 20′, i.e., on a system which is composed of the array of carbon nanotubes 21 and the nano metal paste. While the semiconductor chip arranging step S2 is performed, pressure and/or additional ultrasonic (vibration) may be applied and the semiconductor chip 30 may be preferably positioned on the initial layer 20′. The pressure and the ultrasonic waves (vibrations) improve the coupling quality.

The sintering step S3 is performed so that the initial layer 20′ may be heat-treated at a sintering temperature for the nano metal powder. In the sintering step S3, the resultant structure, which includes the substrate 10, the initial layer 20′, and the semiconductor chip 30, is loaded into an oven with a temperature range of 100° C. to 300° C. The range of the sintering temperature may be varied depending on the kind of metal included in the nano metal powder and the size of the nano metal particles. High temperature causes additives, such as the dispersing agent 23 and the solvent and binder 24, to be volatilized from an interconnection region, allowing the nano-sized metal particles to be sintered between the carbon nanotubes so that the thermal interface material 20 is formed between the substrate and the semiconductor chip. The result is a thermal interface material 20 that is an interconnection layer (i.e., sintered layer) having reliability and excellent thermal conductivity.

According to this exemplary embodiment, the CNT array, i.e., the array of carbon nanotubes 21, causes the interconnection layer corresponding to the thermal interface material 20 to be reinforced with higher strength, so that the desired mechanical strength and reliability is obtained. The thickness of the interconnection layer may be controlled depending on the length of the carbon nanotubes or the array thereof. The length of the carbon nanotubes may be controlled within a range of 100 nm to 100 μm while the diameter of the carbon nanotubes may is be diversified in a range of tens to hundreds of nanometers. Accordingly, the thickness H of the interconnection layer may be controlled to be small from the result of Equation 1, as described above, so that the thermal resistance can be further reduced. The thermal interface material 20, serving as the interconnection layer, may have a thermal conductivity ranging from 200 W/mK to 3000 W/mK, depending on the type of the metal, the length and diameter of carbon nanotubes, the concentration of carbon nanotubes, and the like.

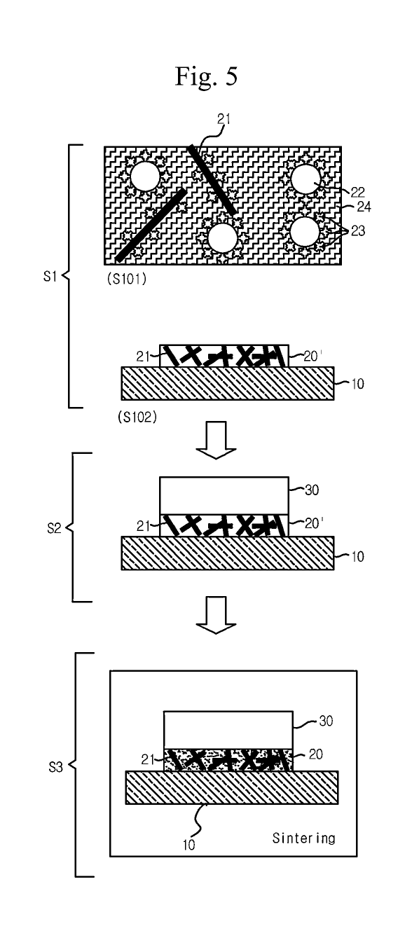

FIG. 5 is a view illustrating a method for forming the thermal interface material 20 which serves as the sintered layer (or the interconnection layer) between the substrate 10 and the semiconductor chip 30 according to a second exemplary embodiment of the present invention. Referring to FIG. 5, this exemplary embodiment also includes the steps as described in the previous exemplary embodiment, i.e., the initial layer forming step S1, the semiconductor chip arranging step S2, and the sintering step S3.

In the first substep S101 of the initial layer forming step S1, a nano metal/CNT paste is provided. The nano metal/CNT paste is a paste in which the nano metal powder and the carbon nanotubes are mixed with each other as the main components. Metal such as Ag, Cu, etc., or metal mixtures thereof may be used as the nano metal powder as described in the previous exemplary embodiment. The particle size of the nano metal powder ranges from 100 nm to 500 nm. The length of the carbon nanotubes may be controlled within the range of 100 nm to 100 μman while the diameter of the carbon nanotubes may be diversified in the range of tens to hundreds of nanometers. The list of the commercial providers of the nano metal powder is identical with that as described above. For example, the carbon nanotubes which are available from Carbon Nanotechnologies Inc. may be used.

In the first substep S101, appropriate amounts of the nano metal particles 22 and is the array of carbon nanotubes 21 are mixed with the dispensing agent 23 and the solvent and the binder 24. The dispensing agent 23 is used to disperse the nano metallic particles 22 and the array of carbon nanotubes 21 and to prevent them from cohering. The binder is used to prevent the paste from degenerating during treatment and drying of the paste, and the solvent may be used to control the viscosity of the paste in some restricted cases. The information on the dispersing agent, the binder, and the solvent has been previously described in the exemplary previous embodiment.

As described above, since the binder should be boiled, evaporated, or decomposed below the sintering temperature, the properties (for example, volatile temperature) of the binder need to match with the sintering temperature of the nano metal powder. Placing the nano metal particles into an ultrasonic bath operating at room temperature or a cold water bath assists in dispersing the nano metal particles in order to prevent the nano metal powder from being heated and, accordingly, sintered. In addition, stirring and/or vibrating may also help disperse the nano metal particles in the binder.

In the second substep S102 of the initial layer forming step S1, the nano metal/CNT paste is applied to the substrate 10 (for example, using dispensing, stenciling, screen printing, or the like) in a similar manner as conventional solder paste or epoxy resin. As such, the nano metal/CNT paste on the substrate 10 forms the initial layer 20′.

Then, the semiconductor chip arranging step S2 is performed so that the semiconductor chip 30 is arranged on the initial layer 20′, which is composed of the nano metal/CNT paste. Applying pressure and additional ultrasonic (vibration) effects during the semiconductor chip arranging step S2 improves the coupling quality and removes almost all gaps and holes, which would otherwise still exist in the initial layer 20′.

The sintering step S3 is performed so that the initial layer 20′ may be heat-treated at a sintering temperature for the nano metal powder. In the same manner as described in the previous exemplary embodiment, the resultant structure, which includes the substrate 10, the initial layer 20′, and the semiconductor chip 30, is loaded into an oven with a temperature range of 100° C. to 300° C. The range of the sintering temperature may be varied depending on what kind of metal is included in the nano metal powder and the size of the nano metal particles. High temperature causes additives, such as the dispersing agent 23 and the solvent and binder 24, to be volatilized from an interconnection region, allowing the nano-sized metal particles to be sintered between the carbon nanotubes so that the thermal interface material 20 is formed between the substrate and the semiconductor chip. The result is a thermal interface material 20 that is an interconnection layer (i.e., sintered layer) having reliability and excellent thermal conductivity.

According to this embodiment, a decrease in the thermal conductivity due to the non-directional dispersion of the array of carbon nanotubes 21 is detected before and after the sintering step, i.e., in the initial layer 20′ and in the sintered layer (i.e., in the thermal interface material 20). Hereinafter, a third embodiment of the present invention which is suitable for preventing a decrease in the thermal conductivity due to the non-directional dispersion of the array of carbon nanotubes 21 will be described.

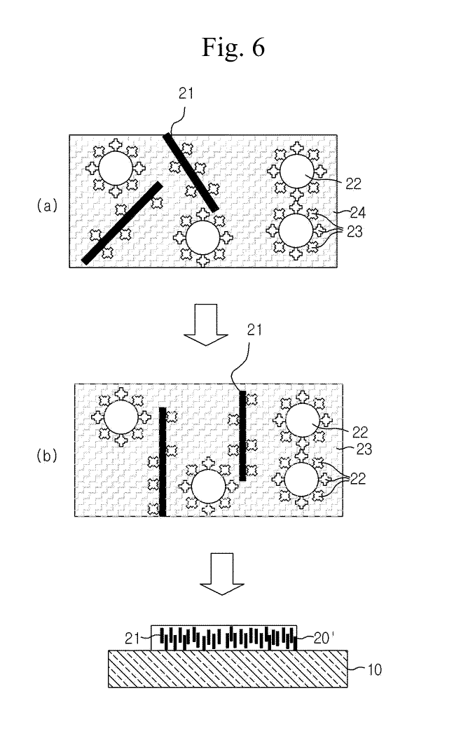

FIG. 6(a) and FIG. 6(b) illustrates a new process (or step) which is added to the previous exemplary embodiment. The new process which may be understood from FIG. 6(a) and FIG. 6(b) is performed after the initial layer forming step S1, as described in the previous exemplary embodiment illustrated in FIG. 5, and more specifically, after the step of providing the nano metal/CNT paste by mixing the array of carbon nanotubes 21 and the nano metal powder with the additives.

The process according to this exemplary embodiment, which runs from FIG. 6(a) to FIG. 6(b), is a process for aligning the array of carbon nanotubes 21 so that the axes thereof may be arranged in the vertical direction in order to improve the thermal conductivity of the nano-metal/CNT paste.

While the nano metal/CNT paste is prepared as a preliminary step, it is necessary to prepare the nano metal/CNT paste with a large amount of the solvent in order to decrease the viscosity of the nano metal/CNT paste.

Then, the array of carbon nanotubes 21 in the nano metal/CNT paste will become aligned as shown in FIG. 6(b). The alignment of the array of carbon nanotubes 21 may be performed as follows.

As a first example, the array of carbon nanotubes 21 can be aligned by exposure to a strong electric or magnetic field. The array of carbon nanotubes 21 may be also doped with an electromagnetic or dipole nano material. For example, chemical absorption of atoms or molecules on an open edge of a single-walled carbon nanotube causes an electric dipole moment or a magnetic moment, so that the array of carbon nanotubes 21 become aligned with their axes arranged in a vertical direction as shown in FIG. 6(b) (e.g., G. Korneva et al. Nano Letters 2005, 5, 879; or http://www.ioffe.ru/IWFAC/2007/abstr/iwfac07_p227_{—}244.pdf, Nanoactuator based on carbon nanotube: new method of control, O. V. Ershova, A. M. Popov, Yu. E. Lozovik, O. N. Bubel, E. F. Kislyakov, and N. A. Poklonski, Institute of Spectroscopy, Troitsk, Moscow Region, Russia, Moscow Institute of Physics and Technology, Dolgoprudny, Moscow Region, Russia, Belorusian State University, Minsk, Belarus; etc).

According to the present invention, it is possible to form the thermal interface material which has significantly improved thermal conductivity, mechanical strength, reliability, is and durability over conventional thermal interface materials. As such, the thermal management of electronic appliances semiconductor chips, including a semiconductor chip (particularly, an optical semiconductor chip), may be considerably improved.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

1. A method for forming a thermal interface material for a semiconductor chip, the method comprising:
forming an initial layer comprising carbon nanotubes and nano metal powder on a substrate;
disposing a semiconductor chip on the initial layer; and
heat-treating the initial layer at a sintering temperature of the nano metal powder to form the thermal interface material,
wherein forming the initial layer comprises:
applying a paste comprising the carbon nanotubes and the nano metal powder to the substrate; and
aligning the carbon nanotubes orthogonally to the plane of the substrate by applying one of an electric field and a magnetic field to the paste.

2-5. (canceled)

6. The method of claim 1, further comprising forming the paste by mixing the carbon nanotubes and the nano metal powder with a binder, a dispersing agent, and a solvent.

7-8. (canceled)

9. The method of claim 1, wherein the binder, the dispersing agent, and the solvent are removed at a temperature below the sintering temperature.

10. A thermal interface material, comprising:
a sintered product made of sintered nano metal powder and carbon nanotubes,
wherein the sintered product is disposed between a substrate and a semiconductor chip.

11. The thermal interface material of claim 10, wherein the carbon nanotubes are disposed on the substrate in a vertical direction and spaced apart from each other to form a carbon nanotube array, and the nano metal powder in a paste state is infiltrated into the carbon nanotube array and then sintered.

12. The thermal interface material of claim 9, wherein the carbon nanotubes and the nano metal powder are interposed between the substrate and the semiconductor chip in the paste state and then sintered.

13. The thermal interface material as claimed in claim 12, wherein the carbon nanotubes are arranged in a vertical direction.

14. An electronic device, comprising:
a substrate;
a semiconductor chip; and
a sintered thermal interface material disposed between the substrate and the semiconductor chip, wherein the sintered thermal interface material comprises a vertical array of carbon nanotubes spaced apart from each other on the substrate and a nano metal powder infiltrated into the vertical array of carbon nanotubes.

15. A method for forming a thermal interface material for a semiconductor chip, the method comprising:
forming an initial layer comprising carbon nanotubes and nano metal powder on a substrate;
disposing a semiconductor chip on the initial layer after forming the initial layer; and
heat-treating the initial layer, semiconductor chip, and the substrate to form the thermal interface material,
wherein forming the initial layer comprises:
growing an array of the carbon nanotubes in a direction orthogonal to the plane of the substrate, the array of carbon nanotubes being spaced apart from each other on the substrate;
providing a paste comprising the nano metal powder; and
applying the paste to the array of the carbon nanotubes, wherein the paste is infiltrated into the array of the carbon nanotubes,
wherein a particle size of the nano metal powder is 100 nm to 500 nm.

16. The method of claim 15, wherein heat-treating the initial layer, semiconductor chip, and the substrate is performed at a sintering temperature of the nano metal powder.

17. The method of claim 15, wherein the nano metal powder is mixed with at least one of a dispensing agent, a binder, and a solvent to form a nano metal paste.

18. The method of claim 17, wherein forming the initial layer comprises applying the nano metal paste to the substrate after growing the carbon nanotubes thereon.

19. The method of claim 18, wherein the semiconductor chip is disposed on the initial layer after forming the initial layer.

20. The method of claim 19, wherein the substrate, initial layer, and the semiconductor chip are subject to the heat-treating.

21. The method of claim 1, wherein the entire initial layer between the semiconductor chip and the substrate is sintered.

22. The method of claim 1, wherein the thermal interface material comprises an interconnection layer contacting the substrate and the semiconductor chip.

23. The method of claim 15, wherein the entire initial layer between the semiconductor chip and the substrate is sintered.

24. The method of claim 15, wherein the thermal interface material comprises an interconnection layer contacting the substrate and the semiconductor chip.
